(19) United States
(12) Patent Application Publication
(10) Pub. No.: US 2007/0275504 A1
(43) Pub. Date: Nov. 29, 2007

(54) Electronic Component Mounting Structure

(75) Inventor: Yasukazu Kishimoto, Yokohama-shi (JP)

Correspondence Address: LOCTITE CORPORATION, 1001 TROUT BROOK CROSSING, ROCKY HILL, CT, 06067, US

(73) Assignee: Henkel Japan, Ltd., Isogo-Ku (JP)

(21) Appl. No.: 11/752,961

(22) Filed: May 24, 2007

(30) Foreign Application Priority Data
May 29, 2006 (JP) 2006-148294

(51) Int. Cl. H01L 21/56; B32B 27/00

(52) U.S. Cl. 438/106; 438/118; 438/127

(57) ABSTRACT

An object of the present invention is to provide an electronic component mounting structure having no degradation of bonding reliability and small warpage at the same time even when a die becomes more extensive in a mounting structure including a semiconductor device carrying a flip-chip mounting.

Such electronic component mounting structure comprises a substrate and a quadrate electronic component mounted on the substrate, wherein a gap between the substrate and the electronic component is filled with a first cured resin filling at least a corner area of the electronic component and a second cured resin filling at least a center area of the electronic component, and a flexural modulus of the first cured resin is higher than a flexural modulus of the second cured resin.

### TECHNICAL FIELD

The present invention relates to an electronic component mounting structure used in an electronic device, and particularly to a semiconductor mounting structure in which a semiconductor die is mounted on a substrate.

### BACKGROUND ART

While semiconductor elements become larger as recent progress in the technology in the field of manufacturing electronic devices, flip-chip mountings, in which semiconductor elements are face-down packed and bonded onto a wiring substrate, have been increasingly employed in order to meet the requirement of reducing electronic devices in size and weight.

In flip-chip mountings, a convex called “bump” is typically set up at an electrode of semiconductor elements, and each electrode is bonded in ways that the bump is face-down opposed to a wiring substrate, which characteristically enables high density mounting compared to wire-bonding mountings. Various designs of flip-chip mountings are known; for example, a bump set up on a wiring substrate, and bonding through electrical-conducting particles without bump.

In flip-clip mountings, the gap between a semiconductor element and a wiring substrate is generally filled with a resin composition such as epoxy resin and anisotropic electrical-conducting materials in order to protect the circuit surface of a semiconductor element from external environment, and at the same time to mechanically bond a semiconductor element and a wiring substrate, or to reduce the thermal stress concentration at the bonding site of electrodes caused by difference in the rate of thermal expansion between a semiconductor element and a wiring substrate.

For example, in JP A 291,805/2001 is described filling the center area of a semiconductor element with a resin composition having a higher flexural modulus and filling the periphery area of the semiconductor element with a resin composition having a lower flexural modulus when mounting the semiconductor element on a substrate. This structure is expected to prevent exfoliation between the semiconductor element and the resin or between the wiring substrate and the resin even when the size of a semiconductor element is large.

As the size of a semiconductor die becomes larger, however the problem of warpage of a mounting structure packed on a substrate arises in addition to the problem of segregation and resultant disconnection, and these problems need to be resolved with consideration of their balance.

### DISCLOSURE OF INVENTION

### Technical Problem

To solve the conventional problem, the present invention has been accomplished and aims at providing an electronic component mounting structure having no degradation of bonding reliability and small warpage at the same time even when a die becomes more extensive in a mounting structure including, a semiconductor device carrying a flip-chip mounting.

### TECHNICAL SOLUTION

The present invention relates to the following.

1. An electronic component mounting structure comprising a substrate and a quadrate electronic component mounted on the substrate,

wherein a gap between the substrate and the electronic component is filled with a first cured resin filling at least a corner area of the electronic component and a second cured resin filling at least a center area of the electronic component, and

a flexural modulus of the first cured resin is higher than a flexural modulus of the second cured resin.

2. The mounting structure according to the above item 1, wherein Lc/Ls is not less than 0.05 in which the Ls represents a side length of the electronic component and the Lc represents a length of a side filled with the first cured resin at the corner area.

3. The mounting structure according to the above items 1 or 2, wherein Lc/Ls is not less than 0.15.

4. The mounting structure according to one of the above items 1 to 3, wherein the flexural modulus of the second cured resin is not more than 0.9 times the flexural modulus of the first cured resin.

5. The mounting structure according to one of the above items 1 to 4, wherein the flexural modulus of the first cured resin is 6 GPa to 15 GPa, and the flexural modulus of the second cured resin is 0.5 GPa to 10 GPa.

6. The mounting structure according to one of the above items 1 to 5, wherein the electronic component is a quadrate semiconductor die.

7. The mounting structure according to one of the above items 1 to 6, wherein the first and second cured resins are a composition or cured same comprising, as a major component, at least one selected from the group consisting of butadiene rubber, nitrile rubber, urethane rubber, silicone rubber, polystyrene, polyvinyl alcohol, methacrylic resin, polyamide, phenolic resin, melamine resin, epoxy resin, bismaleimide resin, imide resin and unsaturated polyester resin

### EFFECT OF THE INVENTION

The present invention is capable of providing an electronic component mounting structure having no degradation of bonding reliability and small warpage at the same time even when a die becomes larger in a mounting structure including a semiconductor device carrying a flip-chip mounting.

### BRIEF DESCRIPTION OF THE DRAWINGS

FIG. 1 is a view showing the electronic component mounting structure according to the present invention.

FIG. 2 is a schematic view showing the layout of the first and second cured resins filled between a substrate and the bottom of an electronic component.

FIG. 3 is a schematic view showing an example of another layout of the first and second cured resins.

FIG. 4 is a schematic view showing an example of another layout of the first and second cured resins.

FIG. 5 is a schematic view showing an example of another layout of the first and second cured resins.

FIG. 6 is a graph showing the relationship between the flexural modulus of the resin composition used in the example and temperature.

### EXPLANATION OF REFERENCE

1 Substrate
2 Electronic component
11 Cured resin
11a First cured resin
11b Second cured resin

### BEST MODE FOR CARRYING OUT THE INVENTION

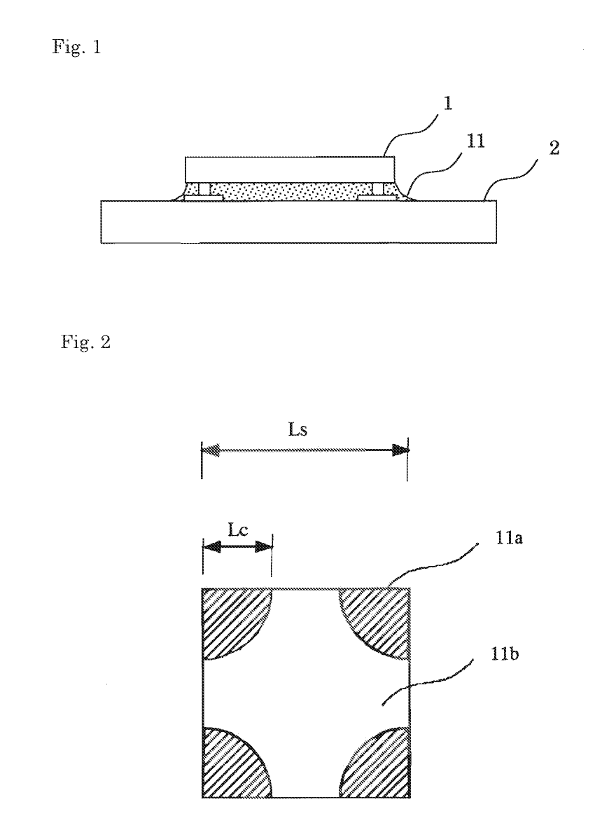

FIG. 1 schematically shows a transverse cross-section of the mounting structure according to the present invention, in which for example, an electronic component (1), such as semiconductor dies, is mounted on a substrate (2), and their gap is filled with a cured resin (11). FIG. 1 schematically shows the cured resin (11) filling the gap under the electronic component (1). As indicated this figure, the space between the electronic component (1) and substrate (2) is filled with the first cured resin (11a) and the second cured resin (11b).

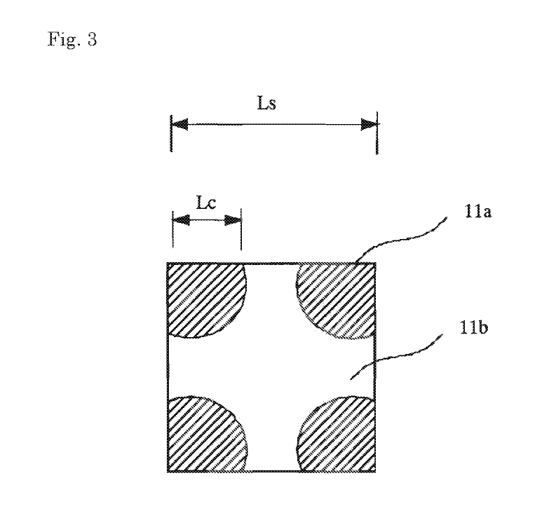

An electronic component (1) is typically a semiconductor die including flip-chips and usually has a quadrate shape including square. As shown in FIG. 2, the first cured resin (11a) fills at least the corner area of the quadrate electronic component (1), and in this example, the second cured resin (11b) fills the space including the center area of the electronic component (1) and excluding the corner area. In this embodiment, the flexural modulus of the first cured resin is higher that the flexural modulus of the second cured resin.

The present inventor's evaluation has revealed that when a resin (cured) having high flexural modulus fills the entire space under an electronic component, such mounting structure has large warpage whereas it has good thermal resistance and thermal-cycling property. When, on the other hand, a resin (cured) having low flexural modulus films the space under an electronic component, such mounting structure has debased thermal-cycling property and degraded reliability whereas the warpage of the structure is small.

In the present invention, more than one resin compositions fill the gap between a substrate and electronic component. A cured resin having low flexural modulus fills a center area which effects warpage, and a cured resin having high flexural modulus fills space including at least a corner area, resulting in high reliability at the same time. It is described to use two resin compositions in JP A 291,805/2001; however, a cured resin having high flexural modulus is used for a center area, resulting in an insufficient improvement in warpage.

The extent of filling with the first cured resin at a corner area may be defined by its ratio in the side length of an electronic component usually quadrate. Given that, as indicated in FIG. 2, Ls is a side length and Lc is the length of a side filled with the first cured resin at a corner area, Lc/Ls is not less than 0.05, preferably not less than 0.1, and more preferably not less than 0.15. If the first cured resin exists at least at a corner area, the first cured resin may fill the entire side (i.e., 2Lc/Ls=1 where 2Lc represents the sum of two Lc of both ends of a side at each corner). For practical work, 2Lc/Ls is preferably not more than 0.9, particularly not more than 0.8.

The second cured resin exists at the center of an electronic component and fills at least 10% or more, preferably 20% or more, more preferably 30% or more, most preferably 40% or more.

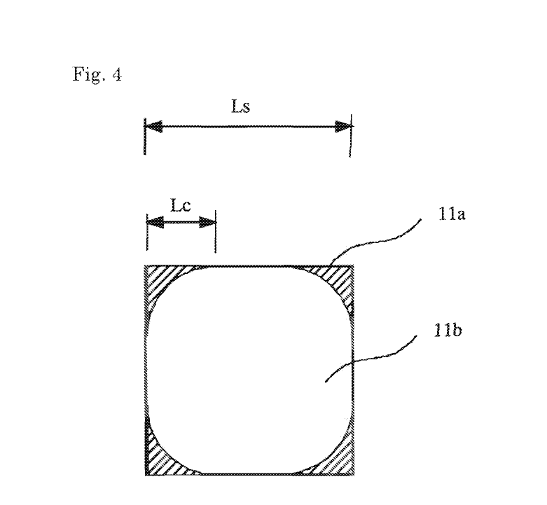

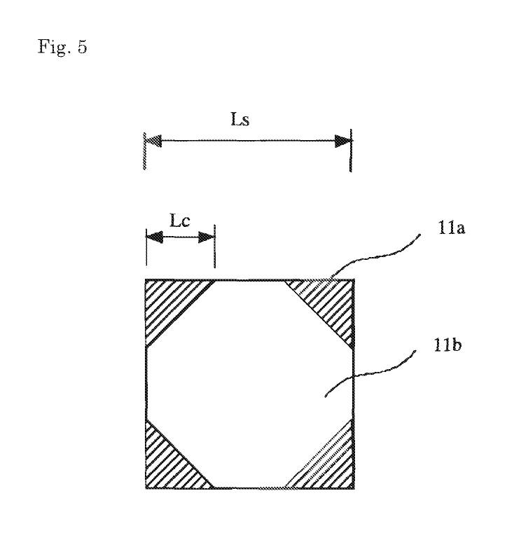

The boundary between the first cured resin and the second cured resin is not specifically restricted, and any shape of same may be employed. FIG. 2 shows quarter circles and their centers are located at each corner, and may also be employed another layout where the circle's centers are located inside the corners as shown in FIG. 3. Naturally such shape is not limited to a part of a perfect circle, and may be employed a part of an ellipse or any other shapes associated with an expanding droplet as being applied. In addition, may be employed arc boundary lines of which convex side face toward corners as shown in FIG. 4, or triangular shapes at corners as shown in FIG. 5.

When an electronic component is not square but rectangular, Lc/Ls preferably meets the above-mentioned condition at least on a short side, and more preferably Lc/Ls also meets the above-mentioned condition on a long side.

In terms of the flexural modulus of the first cured resin and the second cured resin, the flexural modulus of the second cured resin is preferably set not more than 0.9 times the flexural modulus of the first cured resin. In particular, it is preferably within range from 0.1 times to 0.6 times.

In addition, it is preferred that the flexural modulus at room temperature (25° C.) of the first cured resin is 6 GPa to 15 GPa, and the flexural modulus of the above-mentioned second cured resin is 0.5 GPa to 10 GPa. The first cured resin and the second cured resin is selected as a material possessing the above-mentioned flexural modulus and preferably properties suitable for use application. When a resin composition is provided as a cured material, a curing condition is also selected properly in addition to a resin composition before being cured. Specifically may be exemplified the cured materials of resin compositions based on curable resins (for example, thermosetting, light curing, electron beam curing, moisture curing etc.) including polystyrene, polyvinyl alcohol, methacrylic resin, polyamide, bismaleimide resin, imide resin, phenolic resin, melamine resin, epoxy resin, and unsaturated polyester resin. While one of these may be solely utilized, two or more may be combined and used. For the present invention, may also be utilized rubber compositions including butadiene rubber, nitrile rubber, urethane rubber and silicone rubber.

In particular may preferably be employed the cured materials of curable resin compositions including epoxy resin, methacrylic resin and bismaleimide resin.

In the present invention, any substrate possessing metallic wiring may be utilized, in particular may be preferably exemplified organic resin substrates including FR-4 substrate, BT substrate, high Tg FR-4 substrate and FR-5 substrate, and may be further exemplified build-up substrates typically including B2it and ALIVH, flexible substrates and ceramic substrates.

An electronic component is typically semiconductor dies including flip-chips. In addition, an electronic component may preferably be equipped with an electrode for connection and may also be equipped with a bump. Further, an electronic component may be packed in a flip-chip mounting through electrical-conducting particles, and the present invention may be applied to a variety of electronic components mounted face-down on various substrates.

Especially, the size of an electronic component, such as a semiconductor die, to be mounted is preferably 3 mm to 30 mm.

Particularly, is not restricted the method of manufacturing the mounting structures according to the present invention. When both the first and second cured resins are thermosetting resins, a structure may be produced so as to fill corners with the first cured resin by considering the flow characteristics of each resin as being heated and their curing temperatures etc. At a low temperature, usually, the resin composition to give the second cured resin more easily flows than the resin composition to give the first cured resin. Therefore, the first cured resin is able to fill the gap between an electronic component and a substrate including corners by applying a suitable amount of the resin composition to give the first cured resin at the places corresponding to the corners of an electronic component.

### EXAMPLES

The following examples explain the present invention with more details.

### Materials

### 1. Resin composition A (the resin composition to give the first cured resin, high flexural modulus): FP5000 from Henkel Japan Ltd.

Content

Epoxy-based thermosetting resin and curing agent: 45 to 50% by weight

Inorganic filler including silica: 50 to 55% by weight

Flexural Modulus

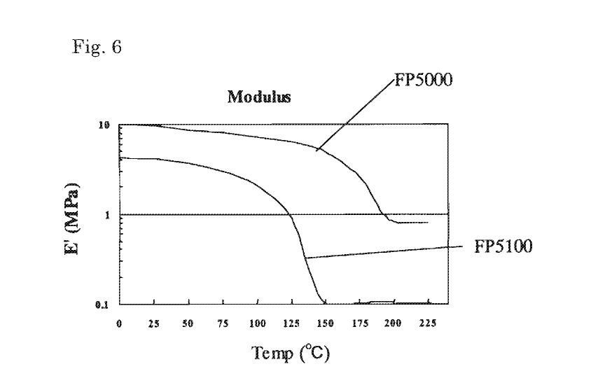

The resin composition consisting of the above-mentioned content was cured at the same curing condition as that of the example to give a mensurative sample piece having 10 mm in width, 1 mm in thickness and 45 mm in length. Its flexural modulus was determined by using DMS 6100 from Seiko Instruments Inc. FIG. 6 shows the resultant data.

### 2. Resin composition B (the resin composition to give the second cured resin, low flexural modulus): FP5100 from Henkel Japan Ltd.

Content

Epoxy-based thermosetting resin and curing agent: 85 to 90% by weight

Silica: 10 to 15% by weight

Flexural Modulus

### FIG. 6 shows the resultant data (the preparation of a sample piece and the method of determination were carried out under the same condition as that for the resin composition A).

### Example 1

At the center of the place on where an electronic component is supposed to be mounted, about 6 mg of the above-mentioned resin composition B was applied on a printed circuit board in which electrode surfaces were plated with Au/Ni (glass epoxy board FR-4 0.1 mm thick, copper foil 18 μm thick). Then, about 4 mg in the total of the above-mentioned resin composition A was applied at the positions corresponding to the four corners of an electronic component. Subsequently, onto that place the silicon chip equipped with copper-plated bumps around its periphery and having 10 mm×10 mm×0.3 mm in size (size of gold stud bump: 50 μm×50 μm×25 μm, number of bump: 200, pitch of bump: 120 μm to 200 μm), as an electronic component, was bonded by application of heat and pressure by using a bonding machine for 4 seconds under the condition of 240° C. and 15 kg/cm². Thus, a sample piece for determining properties was obtained.

The shape of the first cured resin filling under the electronic component thus obtained was substantially the same as shown in FIG. 2, and the radius at a corner was 3.2 mm, meaning that Lc/Ls was 0.32.

### Comparative Example 1

A mensurative sample piece was formed in the same manner as the example 1 except the resin composition B was applied on the place where an electronic component is supposed to be mounted in the example 1.

### Comparative Example 2

A mensurative sample piece was formed in the same manner as the example 1 except the resin composition A was applied on the place where an electronic component is supposed to be mounted in the example 1.

### <Assessment>

Table 1 shows the results of a thermal resistance test and heating-cooling cycle test. A MSL (Mechanical Stress Load test) was carried out by a thermal-pressure test under a saturated-water-vapor atmosphere (temperature: 121° C., 100% RH, 2 atm.) for 1 hour, followed by reflow three times at 250° C. A TCT (Thermal Cycling Test) was conducted by repeating, exposure at −40° C. for 10 minutes and +125° C. for 10 minutes as often as indicated in Table 1. The electrical resistance of nineteen samples was determined before and after each test.

TABLE 1
Thermal resistance and heating-cooling cycle test.
(The values in the table represent electrical resistance by Ω.)

| | Initial | | MSL + TCT | MSL + TCT | MSL + TCT |
|---|---|---|---|---|---|
| | Value | MSL | 200 times | 500 times | 1000 times |
| Example 1 | 5.995 | 6.131 | 6.141 | 6.227 | 6.750 |
| Comparative | 9.14 | 11.415 | 135.48 | | |
| Example 1 | | | | | |
| Comparative | 6.210 | 6.346 | 6.345 | 6.484 | 6.467 |
| Example 2 | | | | | |

In addition, the warpage of each sample piece was determined by using a three-dimensional warpage measuring instrument to determine the overall distribution of warpage. Table 2 shows the resultant data.

TABLE 2

| | Warpage/μm |
|---|---|
| Example 1 | 5.17 |
| Comparative Example 1 | 3.64 |
| Comparative Example 2 | 11.1 |

The above results demonstrate that the mounting structure according to the present invention is capable of achieving a good balance between reliability and warpage within a preferable and practicable range.

1. An electronic component mounting structure comprising a substrate and a quadrate electronic component mounted on the substrate,
wherein a gap between the substrate and the electronic component is filled with a first cured resin filling at least a corner area of the electronic component and a second cured resin filling at least a center area of the electronic component, and
a flexural modulus of the first cured resin is higher than a flexural modulus of the second cured resin.

2. The mounting structure according to claim 1, wherein Lc/Ls is not less than 0.05 in which the Ls represents a side length of the electronic component and the Lc represents a length of a side filled with the first cured resin at the corner area.

3. The mounting structure according to claim 1, wherein Lc/Ls is not less than 0.15.

4. The mounting structure according to claim 1, wherein the flexural modulus of the second cured resin is not more than 0.9 times the flexural modulus of the first cured resin.

5. The mounting structure according to claim 1, wherein the flexural modulus of the first cured resin is 6 GPa to 15 GPa, and the flexural modulus of the second cured resin is 0.5 GPa to 10 GPa.

6. The mounting structure according to claim 1, wherein the electronic component is a quadrate semiconductor die.

7. The mounting structure according to claim 1, wherein the first and second cured resins are a composition or cured same comprising, as a major component, at least one selected from the group consisting of butadiene rubber, nitrile rubber, urethane rubber, silicone rubber, polystyrene, polyvinyl alcohol, methacrylic resin, polyamide, phenolic resin, melamine resin, epoxy resin, bismaleimide resin, imide resin and unsaturated polyester resin.
